(19) United States
(12) Patent Application Publication
(10) Pub. No.: US 2026/0006740 A1
(43) Pub. Date: Jan. 1, 2026

(54) RATCHETING CAM-LATCH FOR SERVER

(71) Applicant: AMD Design, LLC, Wilmington, DE (US)

(72) Inventors: Chen AN, Bergenfield, NJ (US); Mahesh Kumar VARREY, Clifton, NJ (US); Yuan ZHANG, North Bergen, NJ (US)

(73) Assignee: AMD Design, LLC, Wilmington, DE (US)

(21) Appl. No.: 18/755,070

(22) Filed: Jun. 26, 2024

(51) Int. Cl. H05K 7/14

(52) U.S. Cl. CPC H05K 7/1415

(57) ABSTRACT

The ratcheting cam-latch includes a cam that is configured to rotate about a cam rotation-axis. The cam has a cam-in surface with a concave curvature configured to interface with a cam-in feature on a server rack. The cam-in surface has a decreasing radius from the cam rotation-axis in a first direction around the cam rotation-axis. The ratcheting cam-latch also includes a handle mount configured to rotate about a handle rotation-axis that is parallel to the cam rotation-axis and a ratchet disposed between the handle mount and the cam. The ratchet is configured to, responsive to a first rotational force on the handle mount in the first direction, cause the cam to turn in the first direction and, responsive to a second rotational force on the handle mount in a second direction that is opposite the first direction, not cause the cam to turn in the second direction.

### FIELD

This disclosure is directed to a ratcheting cam-latch, an apparatus and a system for installing and/or removing a server from a server rack.

### BACKGROUND

A server often attaches to a server rack via a plurality of connections. For example, a liquid-cooled server may have two liquid quick-disconnect fittings (e.g., one for influent and one for effluent) and at least one electrical connector. To enable the necessary connections to be made, a high insertion force is often required (e.g., at least 200 lbf). Furthermore, there is often a large tolerance in how far the server must be driven along an insertion axis to secure those connections. Further complicating the process of attaching the server to the server rack is the desire to enable quick installation (e.g., no long screws) while maintaining valuable real estate on a front of the server.

### SUMMARY

A ratcheting cam-latch for a server is described herein. The ratcheting cam-latch includes a frame configured to mount to the server and a cam configured to be coupled to the frame and rotate about a cam rotation-axis. The cam has a cam-in surface with a concave curvature configured to interface with a cam-in feature on a server rack and a decreasing radius from the cam rotation-axis in a first direction around the cam rotation-axis. The ratcheting cam-latch also includes a handle mount configured to rotate about a handle rotation-axis that is parallel to the cam rotation-axis and a ratchet disposed between the handle mount and the cam. The ratchet is configured to, responsive to a rotation of the handle mount in the first direction, cause the cam to turn in the first direction and responsive to a rotation of the handle mount in a second direction that is opposite the first direction, not cause the cam to turn in the second direction.

An apparatus for a server is also described herein. The apparatus includes a pair of the ratcheting cam-latches above (e.g., one for each side of the server). The apparatus also includes a handle removably connected to the handle mounts. The handle is configured to cause the handle mounts of the ratcheting cam-latches to rotate in unison when the handle is connected to the handle mounts of the ratcheting cam-latches.

A system is also described herein. The system includes a server frame and the apparatus above. The system may be a server.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of an apparatus including ratcheting cam-latches in accordance with this disclosure.

FIG. 2 illustrates an example of a ratcheting cam-latch with a handle attached thereto in accordance with this disclosure.

FIG. 3 illustrates an example of a system including ratcheting cam-latches in accordance with this disclosure.

FIGS. 4A and 4B illustrate an example of a torque limiter for a handle of an apparatus including ratcheting cam-latches in accordance with this disclosure.

### DETAILED DESCRIPTION

### Overview

Inserting a server into a server rack may require a high insertion force due to various connections being made upon insertion. Furthermore, there is often a large tolerance in travel requirements to secure the connections. Thus, a high insertion-force over a long distance is often required. As servers are being installed in ever increasing numbers (e.g., due to larger numbers in use, maintenance, upgrades, etc.), a need for quick and easy installation of servers is becoming more prevalent while preserving front-end real estate of the servers.

Described herein is ratcheting cam-latch for a server. The ratcheting cam-latch includes a cam that is configured to rotate about a cam rotation-axis. The cam has a cam-in surface with a concave curvature configured to interface with a cam-in feature on a server rack. The cam-in surface has a decreasing radius from the cam rotation-axis in a first direction around the cam rotation-axis. The ratcheting cam-latch also includes a handle mount configured to rotate about a handle rotation-axis that is parallel to the cam rotation-axis and a ratchet disposed between the handle mount and the cam. The ratchet is configured to, responsive to a rotation of the handle mount in the first direction, cause the cam to turn in the first direction and, responsive to a rotation of the handle mount in a second direction that is opposite the first direction, not cause the cam to turn in the second direction.

By using a ratchet to rotate the cam, a long duration of the cam may be utilized (e.g., how far the cam may rotate while still having the cam-in surface interface with the cam-in feature). Doing so enables a high mechanical advantage without a large lever arm (e.g., a handle that extends far away from the server).

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Apparatus

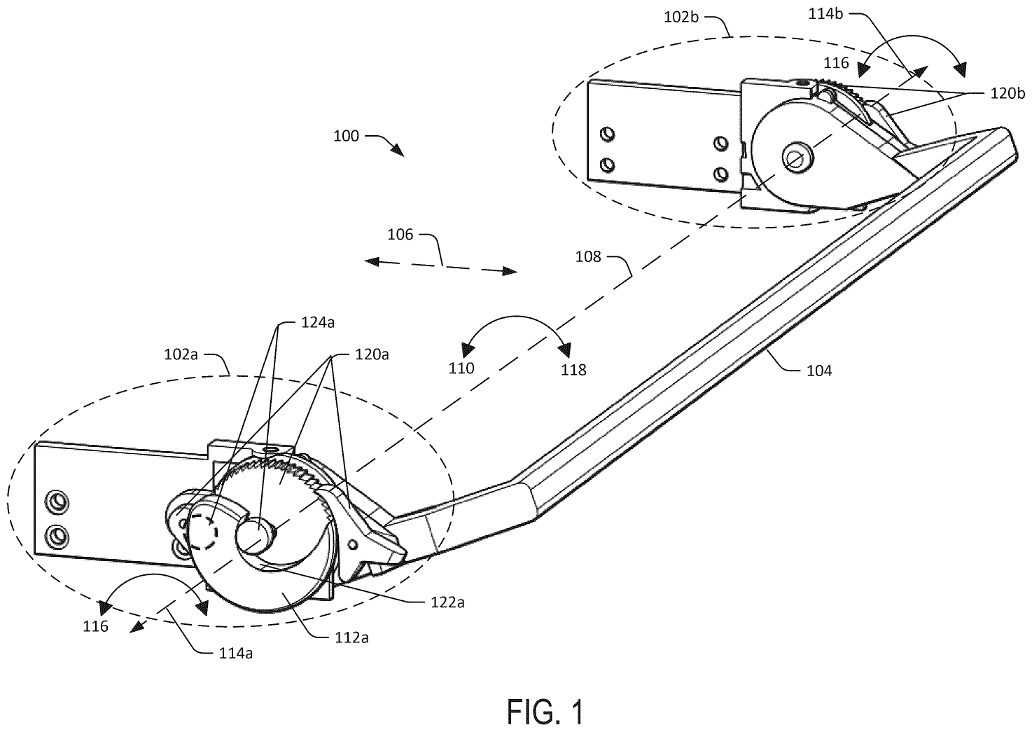

FIG. 1 illustrates an example of an apparatus 100 including two ratcheting cam-latches 102 (e.g., 102a and 102b) and a handle 104 connected therebetween. The apparatus 100 is configured to be attached to a server to drive the server into a server rack along an insertion axis 106. For example, the ratcheting cam-latch 102a may be configured to attach to a left side of a server, and the ratcheting cam-latch 102b may be configured to attach to a right side of the server (when looking at a front of the server).

The ratcheting cam-latches 102 may be mirrors of each other. To enable this, certain parts may be shared and certain parts may be different (depending upon how the ratcheting cam-latches 102 are built).

The apparatus 100 is configured such that, when the handle 104 is rotated about a handle rotation axis 108 in a first handle direction 110 (e.g., due to a first rotational force or moment), cams 112 of the ratcheting cam-latches 102 (e.g., 112a for ratcheting cam-latch 102a and 112b for ratcheting cam-latch 102b, not shown) rotate about cam-rotation axes 114 (e.g., 114a for ratcheting cam-latch 102a and 114b for ratcheting cam-latch 102b) in a first cam direction 116. The apparatus 100 is further configured such that, when the handle 104 is rotated about the handle rotation axis 108 in a second handle direction 118 (e.g., due to a second rotational force or moment), the cams 112 do not rotate about the cam-rotation axes 114. To do so, the ratcheting cam-latches 102 have ratchets 120 (e.g., 120a for ratcheting cam-latch 102a and 120b for ratcheting cam-latch 102b). The ratchets 120 are discussed further below.

The cam-rotation axes 114 may be perpendicular to the insertion axis 106 and are approximately coincident to ensure even pressure along the insertion axis 106. Furthermore, the cams 112 may be configured to rotate together and to be indexed such that the mirrored aspects are maintained during use (e.g., cams 112 are in similar locations about the cam-rotation axes 114).

The handle rotation axis 108 and the cam-rotation axes 114 may be coincident to provide a one-to-one rotation between the handle 104 and the cams 112 (e.g., assuming no intermediate gear sets). The handle rotation axis 108 and the cam-rotation axes 114 may also be parallel and offset to provide a non-one-to-one rotation between the handle 104 and the cams 112 (e.g., for more leverage on the cams 112 if the handle rotation axis 108 is further from the server than the cam-rotation axes 114).

Although the first handle direction 110 is the same as the first cam direction 116 in the illustrated example, they may be opposite. For example, one or more intermediate gears between the handle 104 and the cams 112 may cause the cams 112 to rotate in an opposite direction to the handle 104. The links between rotation directions and relationships of rotation axes may vary without departing from the scope of this disclosure.

The cams 112 have cam-in surfaces 122 (e.g., 122a for ratcheting cam-latch 102a and 122b for ratcheting cam-latch 102b, not shown) that are configured to interface with cam-in features 124a on the server rack (e.g., 124a for ratcheting cam-latch 102a and 124b for ratcheting cam-latch 102b, not shown). The cam-in surfaces 122 have decreasing radii in the first cam direction 116.

The cam-in feature 124a that is dotted illustrates a movement of the apparatus 100 when the cam-in surfaces 122 are in contact with the cam-in features 124 and the cams 112 are rotated in the first cam direction 116. For example, the apparatus 100 may be configured to travel at least 15 millimeters relative to the server rack (e.g., along the insertion axis 106) through rotations of the cams 112 (e.g., based on radial distances between extents of the cam-in surfaces 122).

To enable the travel with a large mechanical advantage, the cam-in surfaces 122 may have long durations. Durations refer to a relationship between rotation of the cams 112 and contact between the cam-in surfaces 122 and the cam-in features 124. For example, the cam-in surfaces 122 may have durations of 180 degrees or more. The ratchets 120 enable the use of the long durations. Without the ratchets 120, the handle 104 would need to rotate 180 degrees to get a similar amount of travel. Doing so is, at a minimum, cumbersome, but most likely impossible. A shorter duration may be used without the ratchets 120; however, a much larger torque may be required on the handle, which may be unfeasible.

The handle 104 may be removably mounted to the ratcheting cam-latches 102 such that the handle 104 may be removed after the server has been fully seated in the server rack. This enables the apparatus 100 to not occlude or block front access to the server when it is installed.

### Example Ratcheting Cam-Latch

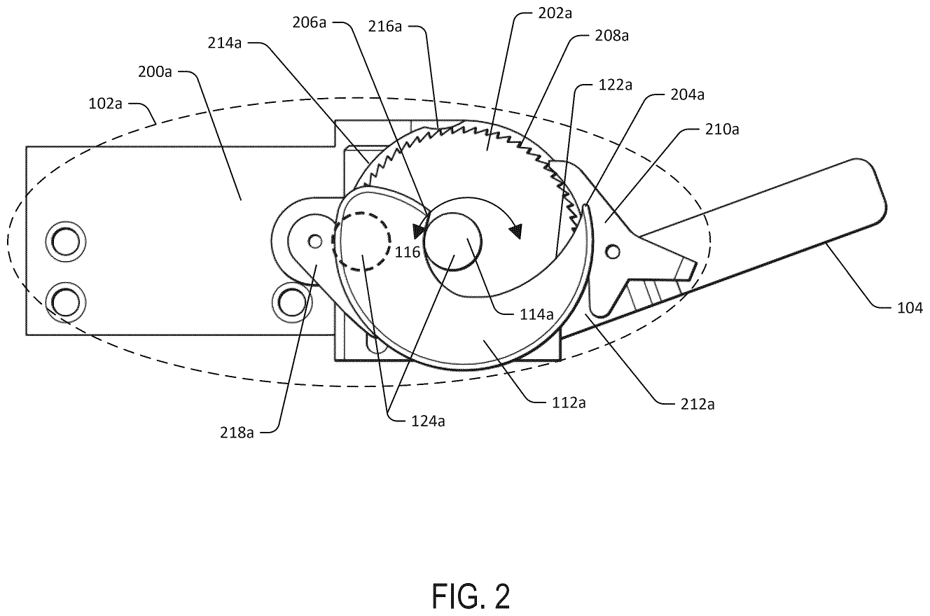

FIG. 2 illustrates an example of the ratcheting cam-latch 102a with the handle 104 attached thereto in accordance with this disclosure. Again, ratcheting cam-latch 102b may be a mirror of ratcheting cam-latch 102a; thus, only the ratcheting cam-latch 102a will be discussed.

The ratcheting cam-latch 102a may include a frame 200a configured to attach to a server (e.g., a frame of the server). The frame 200a may be configured to be bolted, screwed, brazed/welded, clipped, or any other form of mechanical fastening to the server. In some implementations, the frame 200a may be integrated within a frame of the server or not exist. In any case, the cam 112a is configured to be coupled to a side of the server.

Rotatably attached to the frame is the cam 112a. In the illustrated example, the cam 112a is attached to the frame via a wheel 202a. The cam 112a may be attached to the wheel 202a or formed as a portion of the wheel 202a. The cam 112a and the wheel 202a are configured to rotate together around the cam-rotation axis 114a (e.g., relative to the frame 200a).

The cam-in surface 122a of the cam 112a has a decreasing radius (e.g., to the cam-rotation axis 114a) between a leading edge 204a and a trailing edge 206a of the cam-in surface 122a. The decreasing radius is configured to “pull” the server into the server rack when the cam 112a is rotated. The difference in radii between the leading edge 204a and the trailing edge 206a corresponds to a travel distance of the apparatus 100. In some implementations, the leading edge 204 may have a radius that is greater than that of the wheel 202a (as illustrated).

The wheel 202a may have a toothed edge 208a. Teeth of the toothed edge 208a may be asymmetrical (e.g., sawtooth) or symmetrical. An asymmetrical profile may enable the ratchet 102a to be unidirectional, while a symmetrical profile may enable the ratchet 120a to be reversible. By configuring the ratchet 120a to be reversible, similar leverage may be used to rotate the cam 112a out of contact with the cam-in feature 124a (e.g., for server removal). As discussed below, the apparatus 100 may also be configured for removal of the server from the server rack. A reversing ratchet may enable such functionality. In either case, the ratchet 120a may be releasable or configured to be disengaged (e.g., to allow the cam 112a to freewheel and/or rotate in either direction relative to a handle mount 212a).

Engaging with the toothed edge 208a is a pawl 210a. The pawl 210a may be rotatably mounted to a handle mount 212a and spring loaded against the toothed edge 208a. The pawl 210a engages with the toothed edge 208a such that a rotation of the handle mount 212a about the handle rotation axis 108 in the first handle direction 110 (the handle mount 212a connects the handle 104 to the handle rotation axis 108) causes the pawl 210a to grip one or more teeth of the toothed edge 208a and rotate the wheel 202a in the first cam direction 116. When the handle mount 212a is rotated in the second handle direction 118, the pawl 210a is configured to slide across the toothed edge 208a without gripping the teeth; therefore, providing a ratcheting mechanism. If the ratchet 120a is configured as reversible, the opposite also becomes true. For example, when reversed, a rotation of the handle mount 212a in the second handle direction 118 (e.g., due to a third rotational force or moment) causes the pawl 210a to grip the toothed edge 208a, while a rotation of the handle mount 212a in the first handle direction 118 (e.g., due to a fourth rotational force or moment) causes the pawl 210a to slide across the toothed edge 208a. The pawl 210a may be reversible and/or releasable.

The ratchet 120a may vary without departing from the scope of this disclosure. Any device capable of causing a rotation of the cam 112a when the handle mount 212a is rotated in the first handle direction 110 and not causing a rotation of the cam 112a when the handle mount 212a is rotated in the second handle direction 118 (e.g., freewheel, slide, partially disengage, or otherwise decouple relative motion in the second handle direction 118) may be utilized. For example, a one-way clutch (e.g., a sprag clutch or one-way bearing) may be disposed, centered on the handle rotation axis 108, between the handle mount 212a and the cam 112a.

In the illustrated example, the handle rotation axis 108 is coincident with the cam-rotation axis 114a. In some implementations, the handle rotation axis 108 may be offset (e.g., to provide greater leverage/torque on the wheel 202a. Having the handle rotation axis 108 and the cam-rotation axis 114a be coincident may simplify the design and assembly of the ratcheting cam-latch 102a, however.

Between the wheel 202a and the frame 200a may be an indexing disc 214a that is coupled with the cam 112a. The indexing disc 214a may have an indent 216a configured to index the cam 112a to a certain location (e.g., act as a locating detent). For example, a spring-loaded component may slide along an external surface of the indexing disc 214a and spring into the indent 216a at a certain rotation angle. Since the handle 104 is removeable, it may be important to ensure that the cams 112 are in similar locations (e.g., an installation and removal position) when the handle 104 is installed. The indent 216a may also be used in conjunction or separately to manually reverse the cam 112a (e.g., to use as a thumb placement for rotation). There may also be multiple indents.

The ratchet 102a may also have a second pawl 218a that is configured to ensure that the cam 112a does not rotate (e.g., opposite to the first cam direction 116) as the pawl 210a slides along the toothed edge 208a. To do so, the second pawl 210a may also engage the toothed edge 208a. If the ratchet 102a is configured to be reversible, the second pawl 218a may also be reversible to ensure that the cam 112a does not rotate in the first cam direction 116 as the pawl 210a slides along the toothed edge 208 in the opposite direction.

Although not illustrated, the ratcheting cam-latch 102a may also be configured to drive the frame 200a (and, thus, the server), away from the server rack. To do so, there may be a cam-out surface on the cam 112a. The cam-out surface may follow a similar contour as the cam-in surface 122a and be configured to interface with a cam-out feature on the server rack (e.g., a similar feature offset in the insertion direction). As such, the cam 112a may be between the cam-in feature 124a and the cam-out feature on the rack during installation and removal. In another implementation, the cam-in surface 122a may be a surface of a slot formed in the cam 112a. The cam-out surface may be an opposite surface of the slot. Both the cam-in surface 122a and the cam-out surface may interface with the cam-in feature 124a. In such implementations, the cam 112a may resemble a spiral cam.

### Example System

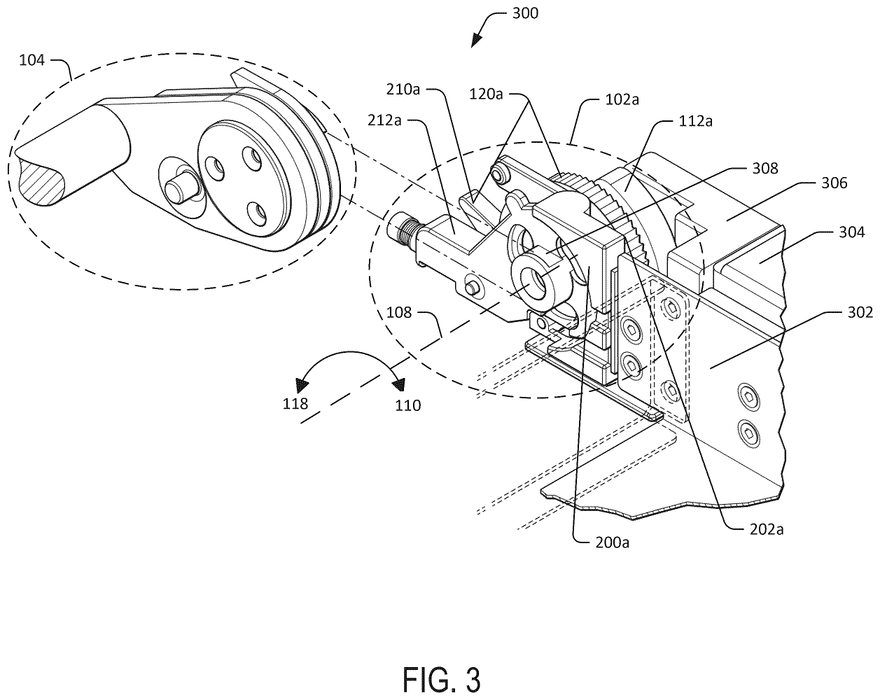

FIG. 3 illustrates an example of a system 300 including the apparatus 100. Only one side of the system 300 is shown (e.g., the left side or the one with the ratcheting cam-latch 102a). The system 300 includes the apparatus 100 (e.g., the ratcheting cam-latch 102a, the ratcheting cam-latch 102b, not shown, and the handle 104), a server frame 302 (which may be part of a server), and a server rack 304. The server rack 304 may include server rack extensions 306 that include the cam-in features 124. In some implementations, the cam-in features 124 may be integral with the server rack 304.

The ratcheting cam-latch 102a includes the frame 200a that is attached to the server frame 302, the cam 112a, the ratchet 120a (e.g., the toothed wheel 202a and the pawl 210a), and the handle mount 212a. The handle mount 212a is configured to rotate about the handle rotation axis 108, which may be coincident with the cam-rotation axis 114a.

To enable the handle 104 to be removed while still able to drive the handle mount 212a, the handle mount 212a may have one or more flats 308a (e.g., flat surfaces). The flats 308a may be configured to interface with a slot in the handle 104. Conversely, the handle mount 212a may have a slot formed therein which slots of the handle 104 may interface with. Any number of mechanisms/features may be used to allow the handle to be removable while still providing torque to the handle mount 212a without departing from the scope of this disclosure.

Once installed, a rotation of the handle 104 in the first handle direction 110 causes the handle mounts 212 to rotate in the first handle direction 110 (e.g., because they are coupled), which causes the ratchets 120 to rotate the cams 112 (either directly or indirectly) in the first cam direction 116. A rotation of the handle 104 in the second handle direction 118 causes the handle mounts 212 to rotate in the second handle direction 118, which causes the ratchets 120 to slip and not rotate the cams 112 in an opposite direction (e.g., the cams 112 stay in their respective positions while the handle 104 is rotated in the second handle direction 118). Continuing those two motions allows the ratcheting cam-latches 102 to “ratchet,” allowing the cam-in surfaces 122 to engage the cam-in features 124 for the long duration of the cams 112 (which may not be possible without the ratchets 120), effectively “pulling” the server frame 302 into the server rack 304).

If the ratchets 120 are reversible, opposite motions of the handle 104 may cause opposite motions. For example, when the ratchets 120 are reversed, a rotation of the handle 104 in the second handle direction 118 causes the handle mounts 212 to rotate in the second handle direction 118, which causes the ratchets 120 to rotate the cams 112 (either directly or indirectly) opposite the first cam direction 116 (e.g., to back out the cam 112a). A rotation of the handle 104 in the first handle direction 110 causes the handle mounts 212 to rotate in the first handle direction 110, which causes the ratchets 120 to slip and not rotate the cams 112 in the first cam direction 116. If the cams 112 are configured with cam-out surfaces, the ratchets 120 may be used to drive the server frame 302 away from the server rack 304 (e.g., for removal).

### Example Torque Limiter

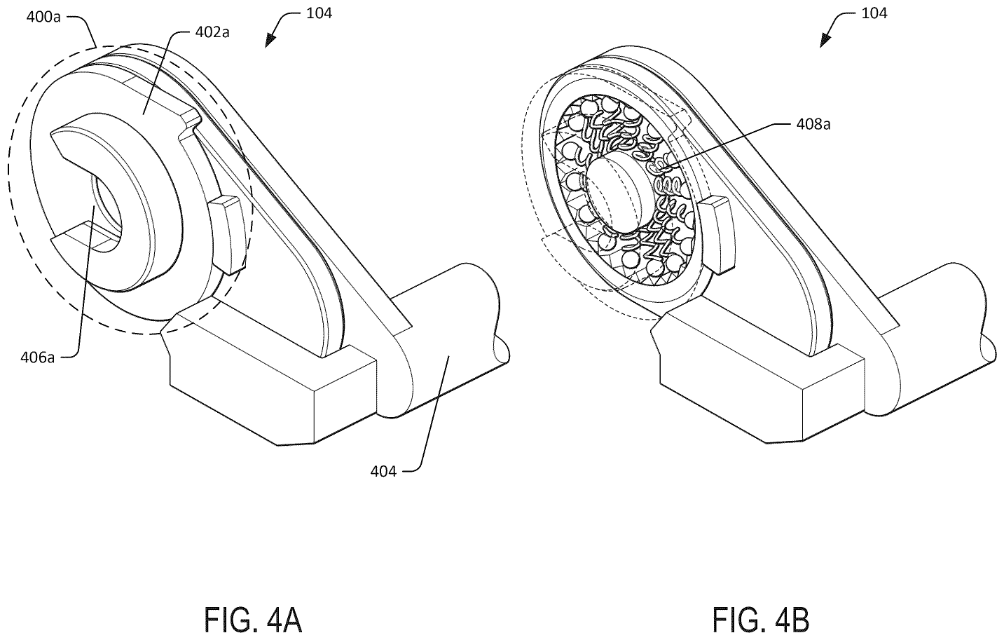

FIGS. 4A and 4B illustrate an example of a torque limiter 400a for the handle 104. It should be noted that only one side of the handle 104 is shown (e.g., the left side) and that the opposite side may be mirrored (e.g., a torque limiter 400b may be disposed on the opposite side of the handle). FIGS. 4A and 4B are similar except that the internals of the torque limiter 400 may be seen.

The torque limiter 400a includes a torque plate 402a that is configured to rotate relative to a handle body 404. The torque plate 402a may have a slot 406a configured to interface with the flats 308a of the handle mount 212a. Conversely, the torque plate 402a may have flats configured to interface with a slot of the handle mount 212a.

The torque limiter 400a consists of a clutch 408a coupling the torque plate 402a to the handle body 404. In normal operation (e.g., with a relatively low torque), the clutch enables the torque generated from a force on the handle body 404 to be transferred to the handle mount 212a. If, however, there is a high torque generated from the handle body 404, the clutch 408a may slip, thereby not transferring the torque to the handle mount 212a. As illustrated, the clutch 408a comprises a plurality of spring-loaded balls interfacing with respective indentations that allow the slipping at higher torques. The clutch 408a may be configured in a variety of other ways without departing from the scope of this disclosure.

### EXAMPLES

Example 1: A ratcheting cam-latch for a server, the ratcheting cam-latch comprising: a frame configured to mount to the server; a cam configured to be coupled to the frame and rotate about a cam rotation-axis, the cam having a cam-in surface with a concave curvature configured to interface with a cam-in feature on a server rack and having a decreasing radius from the cam rotation-axis in a first direction around the cam rotation-axis; a handle mount configured to rotate about a handle rotation-axis that is parallel to the cam rotation-axis; and a ratchet disposed between the handle mount and the cam, the ratchet configured to: responsive to a rotation of the handle mount in the first direction, cause the cam to turn in the first direction; and responsive to a rotation of the handle mount in a second direction that is opposite the first direction, not cause the cam to turn in the second direction.

Example 2: The ratcheting cam-latch of example 1, wherein the cam rotation-axis is perpendicular to an insertion axis.

Example 3: The ratcheting cam-latch of example 1 or 2, wherein the cam rotation-axis is coincident with the handle rotation-axis.

Example 4: The ratcheting cam-latch of any preceding example, wherein the cam-in surface has a duration of at least 180 degrees.

Example 5: The ratcheting cam-latch of any preceding example, wherein a difference in radii between extents of the cam-in surface is at least 15 millimeters.

Example 6: The ratcheting cam-latch of any preceding example, wherein the ratchet includes a wheel attached to the cam and a pawl attached to the handle mount that is spring loaded against the wheel.

Example 7: The ratcheting cam-latch of example 6, wherein a radius of the cam-in surface at an extent of the cam-in surface is larger than a radius of the wheel.

Example 8: The ratcheting cam-latch of any preceding example, wherein the ratchet includes a one-way clutch disposed along the handle rotation-axis and the cam rotation-axis between the handle mount and the cam.

Example 9: The ratcheting cam-latch of any preceding example, wherein the ratchet is releasable effective to allow the cam to rotate in the second direction.

Example 10: The ratcheting cam-latch of any preceding example, wherein: the ratchet is reversible; and the ratchet is further configured to: when reversed, responsive to a rotation of the handle mount in the first direction, not cause the cam to rotate in the first direction; and when reversed, responsive to a rotation of the handle mount in the second direction, cause the cam to rotate in the second direction.

Example 11: The ratcheting cam-latch of example 10, wherein the cam includes a cam-out surface configured to interface with the cam-in feature or a cam-out feature on the server rack, the cam-out surface having a decreasing radius from the cam rotation-axis as the cam rotates in a first direction.

Example 12: The ratcheting cam-latch of any preceding example, wherein the ratcheting cam-latch has a locating detent configured to index a rotation of the cam to an insertion or removal position.

Example 13: The ratcheting cam-latch of any preceding example, wherein the handle mount is configured to interface with a handle.

Example 14: The ratcheting cam-latch of example 13, wherein the handle mount includes one or more flat surfaces configured to interface with the handle.

Example 15: The ratcheting cam-latch of example 13 or 14, wherein the handle includes a torque limiter configured to limit an amount of torque that may be applied to the handle mount via the handle.

Example 16: An apparatus for a server, the apparatus comprising: a pair of ratcheting cam-latches including: respective frames configured to mount to respective sides of the server; respective cams configured to be coupled to the frames and rotate about a cam rotation-axis, the cams having respective cam-in surfaces with a concave curvature configured to interface with respective cam-in features on a server rack and having a decreasing radius from the cam rotation-axis in a first direction around the cam rotation-axis; respective handle mounts configured to rotate about a handle rotation-axis that is parallel to the cam rotation-axis; respective ratchets disposed between the handle mounts and the cams, the ratchets configured to: responsive to a rotation of the handle mounts in the first direction, cause the cams to turn in the first direction; and responsive to a rotation of the handle mounts in a second direction that is opposite the first direction, allow the handle mounts to rotate relative to the cams in the second direction; and a handle removably connected to the handle mounts, the handle configured to cause the handle mounts to rotate in unison when the handle is connected to the handle mounts.

Example 17: The apparatus of example 16, wherein the cam-in surfaces have durations of at least 180 degrees.

Example 18: The apparatus of example 16 or 17, wherein a difference in radii between extents of the cam-in surfaces is at least 15 millimeters.

Example 19: The apparatus of example 16, 17, or 18, wherein the handle includes: slots configured to interface with respective flats on the handle mounts; or flats configured to interface with respective slots on the handle mounts.

Example 20: A system comprising: a server frame; and a pair of ratcheting cam-latches including: respective frames configured to mount to respective sides of the server frame; respective cams configured to be coupled to the frames and rotate about a cam rotation-axis, the cams having respective cam-in surfaces with a concave curvature configured to interface with respective cam-in features on a server rack and having a decreasing radius from the cam rotation-axis in a first direction around the cam rotation-axis; respective handle mounts configured to rotate about a handle rotation-axis that is parallel to the cam rotation-axis; respective ratchets disposed between the handle mounts and the cams, the ratchets configured to: responsive to a rotation of the handle mounts in the first direction, cause the cams to turn in the first direction; and responsive to a rotation of the handle mounts in a second direction that is opposite the first direction, allow the handle mounts to rotate relative to the cams in the second direction; and a handle removably connected to the handle mounts, the handle configured to cause the handle mounts to rotate in unison when the handle is connected to the handle mounts.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description, but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A ratcheting cam-latch for a server, the ratcheting cam-latch comprising:
a cam configured to be coupled to the server and rotate about a cam rotation-axis, the cam having a cam-in surface with a concave curvature configured to interface with a cam-in feature on a server rack and having a decreasing radius from the cam rotation-axis in a first direction around the cam rotation-axis;
a handle mount configured to rotate about a handle rotation-axis that is parallel to the cam rotation-axis; and
a ratchet disposed between the handle mount and the cam, the ratchet configured to:
responsive to a first rotational force on the handle mount in the first direction, cause the cam to turn in the first direction; and
responsive to a second rotational force on the handle mount in a second direction that is opposite the first direction, not cause the cam to turn in the second direction.

2. The ratcheting cam-latch of claim 1, wherein the cam rotation-axis is perpendicular to an insertion axis corresponding to a direction of insertion of the server into the server rack.

3. The ratcheting cam-latch of claim 1, wherein the cam rotation-axis is coincident with the handle rotation-axis.

4. The ratcheting cam-latch of claim 1, wherein the cam-in surface has a duration of at least 180 degrees.

5. The ratcheting cam-latch of claim 1, wherein a difference in radii between extents of the cam-in surface is at least 15 millimeters.

6. The ratcheting cam-latch of claim 1, wherein the ratchet includes a wheel attached to the cam and a pawl attached to the handle mount that is spring loaded against the wheel.

7. The ratcheting cam-latch of claim 6, wherein a radius of the cam-in surface at an extent of the cam-in surface is larger than a radius of the wheel.

8. The ratcheting cam-latch of claim 1, wherein the ratchet includes a one-way clutch disposed along the handle rotation-axis and the cam rotation-axis between the handle mount and the cam.

9. The ratcheting cam-latch of claim 1, wherein the ratchet is configured to be releasable and, when released, allow the cam to freely rotate about the cam rotation-axis.

10. The ratcheting cam-latch of claim 1, wherein:
the ratchet is reversible; and
the ratchet is further configured to:
when reversed, responsive to a third rotational force on the handle mount in the first direction, not cause the cam to rotate in the first direction; and
when reversed, responsive to a fourth rotational force on the handle mount in the second direction, cause the cam to rotate in the second direction.

11. The ratcheting cam-latch of claim 10, wherein the cam includes a cam-out surface configured to interface with the cam-in feature or a cam-out feature on the server rack, the cam-out surface having a decreasing radius from the cam rotation-axis as the cam rotates in a first direction.

12. The ratcheting cam-latch of claim 1, wherein the ratcheting cam-latch has a locating detent configured to index a rotation of the cam to an insertion or removal position.

13. The ratcheting cam-latch of claim 1, wherein the handle mount is configured to interface with a handle.

14. The ratcheting cam-latch of claim 13, wherein the handle mount includes one or more flat surfaces configured to interface with the handle.

15. The ratcheting cam-latch of claim 13, wherein the handle includes a torque limiter configured to limit an amount of torque that may be applied to the handle mount via the handle.

16. An apparatus for a server, the apparatus comprising:
a pair of ratcheting cam-latches including:
respective cams configured to be coupled to respective sides of the server and rotate about a cam rotation-axis, the cams having respective cam-in surfaces with a concave curvature configured to interface with respective cam-in features on a server rack and having a decreasing radius from the cam rotation-axis in a first direction around the cam rotation-axis;
respective handle mounts configured to rotate about a handle rotation-axis that is parallel to the cam rotation-axis;
respective ratchets disposed between the handle mounts and the cams, the ratchets configured to:
responsive to a first rotational force on the handle mounts in the first direction, cause the cams to turn in the first direction; and
responsive to a second rotational force on the handle mounts in a second direction that is opposite the first direction, allow the handle mounts to rotate relative to the cams in the second direction; and
a handle removably connected to the handle mounts, the handle configured to cause the handle mounts to rotate in unison when the handle is connected to the handle mounts.

17. The apparatus of claim 16, wherein the cam-in surfaces have durations of at least 180 degrees.

18. The apparatus of claim 16, wherein a difference in radii between extents of the cam-in surfaces is at least 15 millimeters.

19. The apparatus of claim 16, wherein the handle includes:
slots configured to interface with respective flats on the handle mounts; or
flats configured to interface with respective slots on the handle mounts.

20. A system comprising:
a server frame; and
a pair of ratcheting cam-latches including:
respective cams configured to be coupled to respective sides of the server frame and rotate about a cam rotation-axis, the cams having respective cam-in surfaces with a concave curvature configured to interface with respective cam-in features on a server rack and having a decreasing radius from the cam rotation-axis in a first direction around the cam rotation-axis;
respective handle mounts configured to rotate about a handle rotation-axis that is parallel to the cam rotation-axis;
respective ratchets disposed between the handle mounts and the cams, the ratchets configured to:
responsive to a first rotational force on the handle mounts in the first direction, cause the cams to turn in the first direction; and
responsive to a second rotational force on the handle mounts in a second direction that is opposite the first direction, allow the handle mounts to rotate relative to the cams in the second direction; and
a handle removably connected to the handle mounts, the handle configured to cause the handle mounts to rotate in unison when the handle is connected to the handle mounts.
